(19) United States
(12) Patent Application Publication
(10) Pub. No.: US 2019/0326462 A1
(43) Pub. Date: Oct. 24, 2019

(54) PHOTOVOLTAIC REFLECTIVE FILM AND APPLICATION THEREOF

(71) Applicant: SUZHOU GOLDEN STAR ELECTRONIC TECHNOLOGY CO., LTD, Jiangsu (CN)

(72) Inventors: Rui GAO, Jiangsu (CN); Jing DING, Jiangsu (CN)

(21) Appl. No.: 16/470,906

(22) PCT Filed: Apr. 12, 2017
(86) PCT No.: PCT/CN2017/080244

§ 371 Date: Jun. 18, 2019

(30) Foreign Application Priority Data
Dec. 22, 2016 (CN) 201611201822.1
Dec. 22, 2016 (CN) 201611201823.6
Dec. 22, 2016 (CN) 201611201825.5

(51) Int. Cl. H01L 31/054; G02B 5/04

(52) U.S. Cl. CPC H01L 31/0547; G02B 5/045

(57) ABSTRACT

The present invention provides a photovoltaic reflective film, comprising a substrate and a micro-structural reflective layer arranged on the upper surface of the substrate, wherein the micro-structural reflective layer comprises a micro-structural layer and a reflective layer; the micro-structural layer is composed of a plurality of polygonal pyramids, micro triangular prisms or micro-prisms. The micro-structural reflective layer can effectively increase the area of a reflective surface, and can reflect incident light in multiple directions, so that the light is absorbed by the surface of cells in a larger area to be converted into electrical energy, thus the utilization of light energy is improved, and the output power of a photovoltaic module is increased.

### FIELD OF THE INVENTION

The present invention relates to a reflective film, particularly to a photovoltaic reflective film applied to a photovoltaic module.

### BACKGROUND OF THE INVENTION

Photovoltaic welding strips are used for the connection between cells of a photovoltaic module to play an important role in electric conduction and concentration. In order to ensure reliable welding between the welding strips and the cells and prevent corrosion of the welding strips, the surface of the welding strips is coated with a tin layer. When sunlight irradiates the surface of the welding strips, the tin layer directly reflects the sunlight, and this part of sunlight cannot be used by a cell panel, causing waste of light energy.

Part of a welding strip body is provided with a stripe structure for reflecting light. However, since the base material of the welding strips is copper, the stripe structure is hardly made into a micro-structure during processing, so the reflection effect is not satisfactory, and the thickness of the surface tin layer may be uneven, which easily causes breakage of the cells to affect the production efficiency.

### SUMMARY OF THE INVENTION

In order to overcome the above deficiencies of the prior art, an objective of the present invention is to provide a photovoltaic reflective film which is simple in structure and low in cost and can fully utilize light.

In order to achieve the above objective, the technical solution adopted by the present invention to solve the technical problems is that:

A photovoltaic reflective film, comprises a substrate and a micro-structural reflective layer arranged on the upper surface of the substrate; the micro-structural reflective layer includes a micro-structural layer and a reflective layer coated on the surface of the micro-structural layer, and the micro-structural layer is composed of a plurality of polygonal pyramids, micro triangular prisms or micro-prisms.

Compared with the prior art, the present invention has the advantages that the reflective micro-structure can reflect incident light in multiple directions leading to being reabsorbed by cells, so that the area of the reflective surface is effectively increased, the reflected light reaching the surface of the cells in a larger area is reused, the utilization of light energy is improved, and the output power of a photovoltaic module is increased.

Further, the photovoltaic reflective film further includes a fixed adhesive layer or a back adhesive layer, and the fixed adhesive layer or the back adhesive layer is arranged on the lower surface of the substrate.

Further, the polygonal pyramids of the micro-structural layer are preferably rectangular pyramids.

With the preferred solution, the pyramid structure uniformly reflects the incident light to the surface of the cells in four directions, so that the utilization of light is higher, and the structure is also more stable.

Further, the bottom edges of the rectangular pyramids are arranged at an angle of 45° to the length direction of the substrate.

With the preferred solution, the length direction of welding strips of the photovoltaic module is consistent with the direction of main grid lines of the cells, and the bottom edges of the rectangular pyramids are arranged at an angle of 45° thereto, so that the reflected light can be diverged in four directions without being reflected onto the reflective film on the surface of the welding strips.

Further, the quadrangular pyramids have a multi-slope structure, and the angles of slopes of the ridges decrease successively from bottom to top.

With the preferred solution, the height of the quadrangular pyramids is reduced; the space is saved; the reflection area is increased, and the efficiency of the photovoltaic module is improved.

Further, the quadrangular pyramids have an apex angle of 50°-75°.

With the preferred solution, the structural stability is ensured while the area of the reflective film is increased.

Further, the quadrangular pyramids have a bottom edge length of 50 μm.

With the preferred solution, the reflected light can be reused better by refining the micro-structure under the guarantee of the production capacity of a mold.

A photovoltaic reflective film, including a substrate, a micro-structural reflective layer, and a fixed adhesive layer, wherein the micro-structural reflective layer is arranged on the upper surface of the substrate. The micro-structural reflective layer includes a micro-structural layer and a reflective layer; the reflective layer is coated on the surface of the micro-structural layer, and the fixed adhesive layer is arranged on the lower surface of the substrate. The micro-structural layer is composed of a plurality of micro triangular prisms continuously arranged in the side direction; one side of the micro triangular prisms is arranged on the upper surface of the substrate, and the ridge direction of the micro triangular prisms is parallel to the length direction of the substrate.

Compared with the prior art, the present invention has the advantages that the triangular prisms of the micro-structural layer are horizontal, so that the area of the reflective surface is effectively increased; the reflected light reaching the surface of cells in a larger area is reused, the utilization of light energy is improved, and the output power of the photovoltaic module is increased.

Further, the micro triangular prisms have an apex angle of 60°-150°, preferably 120°.

With the preferred solution, the structural stability is ensured while the area of the reflective film is increased.

Further, the micro triangular prisms have a bottom width of 50 μm.

With the preferred solution, the reflected light can be reused better by refining the micro-structure under the guarantee of the production capacity of a mold.

Further, the top of the micro triangular prism is cut into a multi-pointed concave and convex structure.

With the preferred solution, the height of the micro-structure is reduced; the space is saved; the vertical reflective surface is effectively increased, and the incident light having high illumination intensity and small incident angle is better utilized.

A photovoltaic reflective film, including a substrate, a fixed adhesive layer, a micro-prism layer, and a reflective layer, wherein the fixed adhesive layer is arranged on the lower surface of the substrate; the micro-prism layer is composed of a plurality of micro-prism arrays and arranged on the upper surface of the substrate. The reflective layer covers the surface of the micro-prism layer, and the ridge direction of the micro-prisms is arranged at an angle of 15°-65° to the length direction of the substrate.

Compared with the prior art, the present invention has the advantages that the ridge direction of the micro-prisms is arranged at an angle to the length direction of the substrate, so that the area of the reflective surface is increased, the reflected light reaching the surface of cells in a larger area is reused, the utilization of light energy is improved, and the output power of the photovoltaic module is increased.

Further, the angle between the ridge direction of the micro-prisms and the length direction of the substrate is preferably 45°.

With the preferred solution, 45° is preferred in combination with the geographical and illumination characteristics of main photovoltaic use places to improve the versatility of the reflective film.

Further, the micro-prisms have an apex angle of 60°-150°, preferably 120°.

With the preferred solution, the structural stability is ensured while the area of the reflective film is increased.

Further, the micro-prisms have a bottom width of 50 μm.

With the preferred solution, the reflected light can be reused better by refining the micro-structure under the guarantee of the production capacity of a mold.

Further, a plurality of W-shaped pointed structures are arranged on one side of the micro-prism.

With the preferred solution, W-shaped pointed structures are arranged on the main light receiving surface of the micro-prisms, thereby effectively increasing the area of the reflective film and improving the utilization of light energy.

Further, the micro-prism layer is provided with a plurality of V-shaped grooves, and the bottom edges of the V-shaped grooves are perpendicular to the bottom edges of the micro-prisms.

With the preferred solution, the reflective surface becomes tetrahedrons of micro-structural units, so that the reflective surface is effectively increased, and the reflected light is totally reflected by a glass sheet and then uniformly reaches the surface of cells.

Further, the V-shaped grooves have an opening width of 50 μm.

With the preferred solution, uniform tetrahedrons consistent with the prisms in size are constituted to ensure uniform reflection of light.

An application of the photovoltaic reflective film, wherein the photovoltaic reflective film is applied to a photovoltaic module to improve the power of the photovoltaic module; the photovoltaic module includes a plurality of cells and welding strips for connecting the cells; the photovoltaic reflective film is arranged on the upper surface of the welding strips or in gaps between the cells, and the photovoltaic reflective film may also be simultaneously arranged on the upper surface of the welding strips and in gaps between the cells. The length direction of the photovoltaic reflective film is parallel to that of the welding strips or that of the gaps in the length direction.

By adopting the above preferred solution, the reflective film is arranged at a spatial position where light is not utilized in the photovoltaic module, and the light is reflected to the surface of the cells and converted into electrical energy, so that the power generated by the photovoltaic module is improved.

### BRIEF DESCRIPTION OF THE DRAWINGS

In order to describe the technical solutions in the embodiments of the present invention or in the prior art more clearly, the following briefly introduces the accompanying drawings required for describing the embodiments or the prior art. Apparently, the accompanying drawings in the following description show only some embodiments of the present invention, and a person of ordinary skill in the art may still derive other drawings from these accompanying drawings without creative efforts.

FIG. 1 is a structure diagram according to an embodiment of the present invention;

FIG. 2 is a structure diagram of a multi-slope structure of a rectangular pyramid according to the present invention;

FIG. 3 is a structure diagram according to another embodiment of the present invention;

FIG. 4 is a structure diagram of a multi-pointed structure of micro triangular prisms according to the present invention;

FIG. 5 is a structure diagram according to another embodiment of the present invention;

FIG. 6 is a structure diagram of a W-shaped pointed structure of micro-prisms according to the present invention;

FIG. 7 is a structure diagram of V-shaped grooves of micro-prisms according to the present invention;

FIG. 8 is a structure diagram of a photovoltaic module;

FIG. 9 is a principle diagram of light reflection in the photovoltaic module according to the present invention.

Signs of corresponding parts represented by numerals and letters in the drawings: 1-substrate; 2-micro-structural reflective layer; 21-micro-structural layer; 211-multi-pointed structure; 22-reflective layer; 23-micro-prism layer; 231-W-shaped pointed structure; 232-V-shaped groove; 3-fixed adhesive layer; 4-photovoltaic module; 41-cell; 42-welding strip; 43-photovoltaic reflective film; 44-glass sheet; 51-incident light; 52-reflected light; 53-total reflected light.

### DETAILED DESCRIPTION OF THE EMBODIMENTS

A clear and complete description will be made to the technical solutions in the embodiments of the present invention below in combination with the accompanying drawings in the embodiments of the present invention. Apparently, the embodiments described are only a part of, instead of all of the embodiments of the present invention. All other embodiments obtained by a person of ordinary skill in the art based on the embodiments of the present invention without creative efforts shall fall within the protection scope of the present invention.

In order to achieve the objective of the present invention, as shown in FIG. 1, an embodiment of the present invention is: a photovoltaic reflective film includes a substrate 1, a micro-structural reflective layer 2, and a fixed adhesive layer 3, wherein the fixed adhesive layer 3 is arranged on the lower surface of the substrate 1; the micro-structural reflective layer 2 is arranged on the upper surface of the substrate 1; the micro-structural reflective layer 2 includes a micro-structural layer and a reflective layer; the reflective layer is coated on the surface of the micro-structural layer; the micro-structural layer is composed of a plurality of polygonal pyramids, and the bottom surface of the polygonal pyramids is arranged on the surface of the substrate 1.

The beneficial effects of the technical solution are: the micro-structural layer is composed of polygonal pyramids, which can reflect incident light in multiple directions to be reabsorbed by cells, so that the area of the reflective surface is effectively increased, the reflected light reaching the surface of the cells in a larger area is reused, the utilization of light energy is improved, and the output power of the photovoltaic module is increased.

In some other embodiments of the present invention, the polygonal pyramids of the micro-structural layer are preferably rectangular pyramids for the purpose of better improving the utilization of light. The beneficial effects of the technical solution are: the pyramid structure uniformly reflects the incident light to the surface of the cells in four directions, so that the utilization of light is high, and the structure is also the most stable.

In some other embodiments of the present invention, the bottom edges of the rectangular pyramids are arranged at an angle of 45° to the length direction of the substrate for the purpose of improving the light reflecting path. The beneficial effects of the technical solution are: the length direction of welding strips of a photovoltaic module is consistent with the direction of main grid lines of cells, and the bottom edges of the rectangular pyramids are arranged at an angle of 45° thereto, so that the reflected light can be diverged in four directions without being reflected onto the reflective film on the surface of the welding strips.

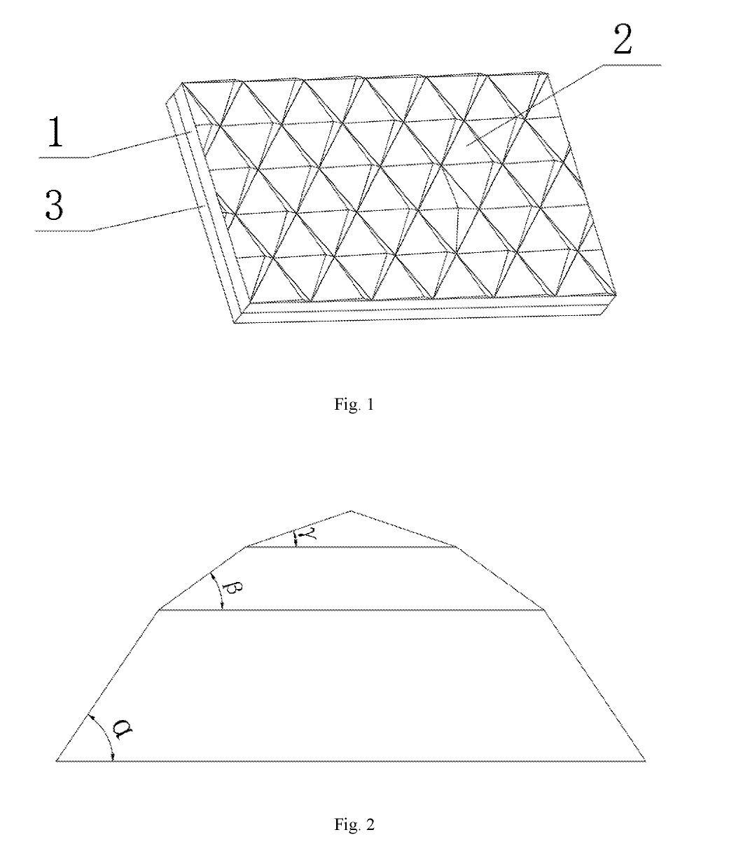

As shown in FIG. 2, in some other embodiments of the present invention, in order to achieve the purpose of saving space, the quadrangular pyramids have a multi-slope structure, the angles of slopes of the ridges decrease successively from bottom to top, and α>β>γ. The beneficial effects of the technical solution are: the height of the quadrangular pyramids is reduced, the space is saved, the reflection area is increased, and the efficiency of the photovoltaic module is improved.

In some other embodiments of the present invention, the quadrangular pyramids have an apex angle of 50°-75° for the purpose of improving the stability of the micro-structure. The beneficial effects of the technical solution are: the structural stability is ensured while the area of the reflective film is increased.

In some other embodiments of the present invention, the pyramidal pyramids have a bottom edge length of 50 μm for the purpose of refining the micro-structure. The beneficial effect of the technical solution is: the reflected light can be reused better by refining the micro-structure under the guarantee of the production capacity of a mold.

In order to achieve the objective of the present invention, as shown in FIG. 3, an embodiment of the present invention is: a photovoltaic reflective film includes a substrate 1, a micro-structural reflective layer, and a fixed adhesive layer 3, wherein the micro-structural reflective layer 2 is arranged on the upper surface of the substrate 1, the micro-structural reflective layer includes a micro-structural layer 21 and a reflective layer 22, the reflective layer 22 is coated on the surface of the micro-structural layer 21, the fixed adhesive layer 3 is arranged on the lower surface of the substrate 1, the micro-structural layer 21 is composed of a plurality of micro triangular prisms continuously arranged in the side direction, one side of the micro triangular prisms is arranged on the upper surface of the substrate 1, and the ridge direction of the micro triangular prisms is parallel to the length direction of the substrate 1.

The beneficial effects of the technical solution are: the triangular prisms of the micro-structural layer are horizontal, so that the area of the reflective surface is effectively increased, the reflected light reaching the surface of cells in a larger area is reused, the utilization of light energy is improved, and the output power of the photovoltaic module is increased.

In some other embodiments of the present invention, the micro triangular prisms have an apex angle of 60°-150°, preferably 120°, for the purpose of improving the stability of the reflective structure. The beneficial effects of the technical solution are: the structural stability is ensured while the area of the reflective film is increased.

In some other embodiments of the present invention, the micro triangular prisms have a bottom width of 50 μm for the purpose of refining the micro-structure. The beneficial effect of the technical solution is: the reflected light can be reused better by refining the micro-structure under the guarantee of the production capacity of a mold.

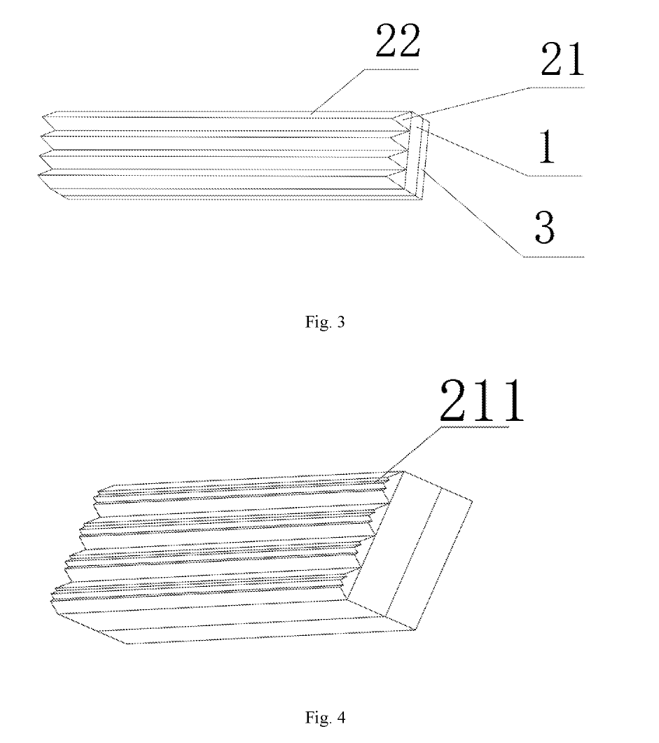

As shown in FIG. 4, in some other embodiments of the present invention, in order to save the space and increase the effective reflection area, the top of the micro triangular prism is cut into a multi-pointed concave and convex structure, and the vertical reflective surface is also effectively increased. The beneficial effects of the technical solution are: the height of the micro-structure is reduced, the space is saved, and the incident light having high illumination intensity and small incident angle is better utilized.

In order to achieve the objective of the present invention, as shown in FIG. 5, an embodiment of the present invention is: a photovoltaic reflective film includes a substrate 1, a fixed adhesive layer 3, a micro-prism layer 23, and a reflective layer 22, wherein the fixed adhesive layer 3 is arranged on the lower surface of the substrate 1, the micro-prism layer 23 is composed of a plurality of micro-prism arrays and arranged on the upper surface of the substrate 1, the reflective layer 22 covers the surface of the micro-prism layer 23, and the ridge direction of the micro-prisms is arranged at an angle of 15°-65° to the length direction of the substrate.

The beneficial effects of the technical solution are: the ridge direction of the micro-prisms is arranged at an angle to the length direction of the substrate, so that the area of the reflective surface is increased, the reflected light reaching the surface of cells in a larger area is reused, the utilization of light energy is improved, and the output power of the photovoltaic module is increased.

The angle of sunlight is different at different latitudes, for example, the optimal angle between the ridge direction of the micro-prisms and the length direction of the substrate is different in Xinjiang and Jiangsu, and may be correspondingly adjusted according to the angle of sunlight. In some other embodiments of the present invention, the angle between the ridge direction of the micro-prisms and the length direction of the substrate is preferably 45° for the purpose of achieving versatility in the production of the reflective film. The beneficial effect of the technical solution is: 45° is preferred in combination with the geographical and illumination characteristics of main photovoltaic use places to improve the versatility of the reflective film.

In some other embodiments of the present invention, the micro-prisms have an apex angle of 60°-150°, preferably 120°, for the purpose of improving the structural stability of the reflective film. The beneficial effects of the technical solution are: the structural stability is ensured while the area of the reflective film is increased.

In some other embodiments of the present invention, the micro-prisms have a bottom width of 50 μm for the purpose of refining the micro-structure. The beneficial effect of the technical solution is: the reflected light can be reused better by refining the micro-structure under the guarantee of the production capacity of a mold.

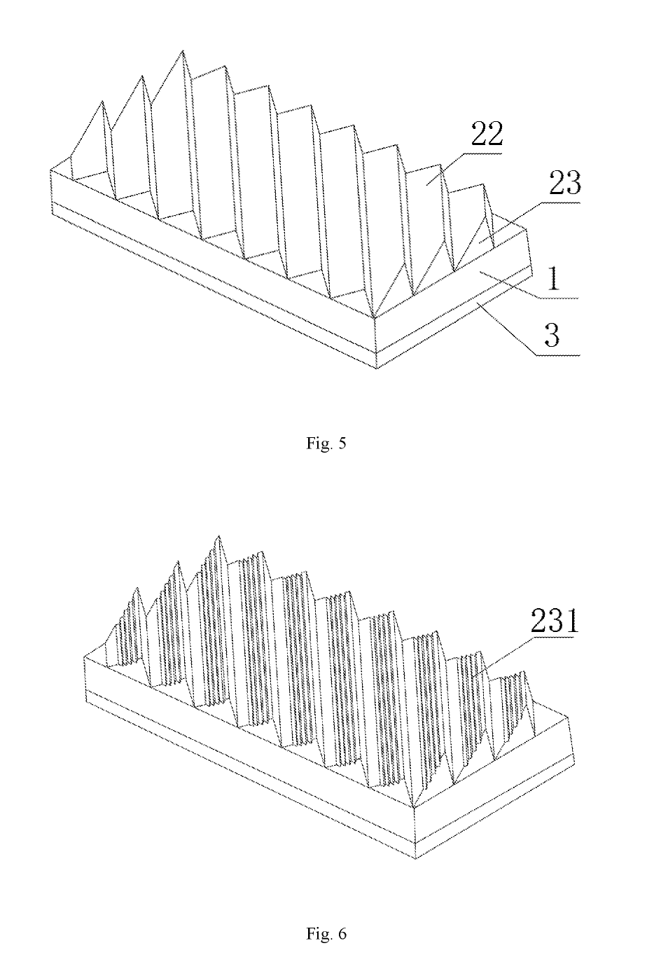

As shown in FIG. 6, in some other embodiments of the present invention, in order to achieve a larger increase in the area of the reflective film, a plurality of W-shaped pointed structures 231 is arranged on one side of the micro-prism where the sunlight is concentrated. The beneficial effects of the technical solution are: the area of the reflective film is effectively increased, the reflected light reaches the surface of cells in a larger area, and the utilization of light energy is improved.

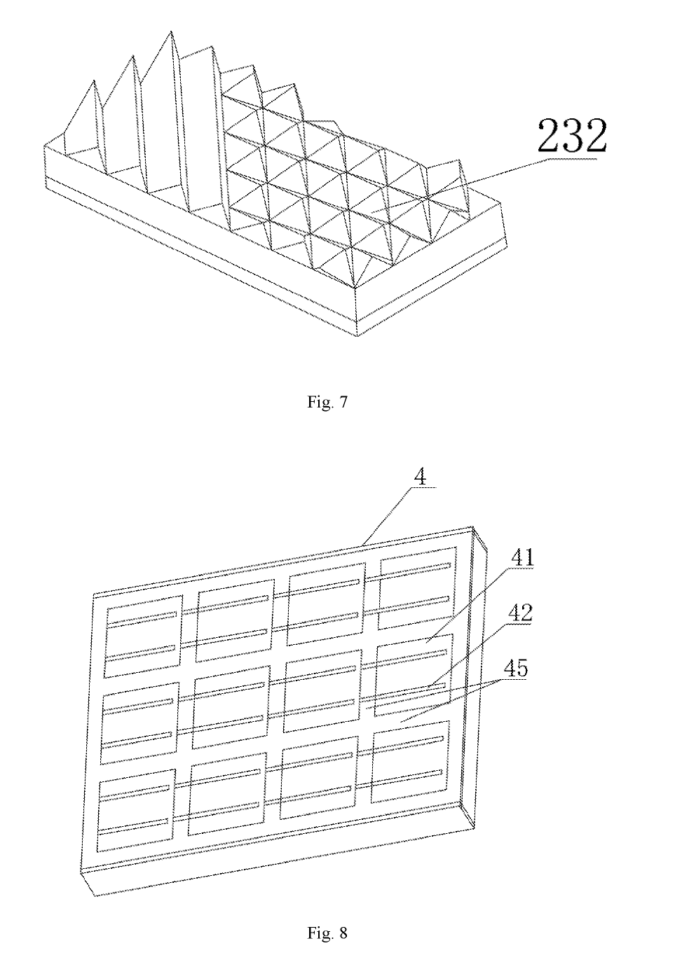

As shown in FIG. 7, in some other embodiments of the present invention, in order to further increase the effective reflective surface, the micro-prism layer 3 is provided with a plurality of V-shaped grooves 232, and the bottom edges of the V-shaped grooves 232 are perpendicular to the bottom edges of the micro-prisms. The beneficial effects of the technical solution are: the reflective surface becomes tetrahedrons of micro-structural units, so that the reflective surface is effectively increased, and the reflected light is totally reflected by a glass sheet and then uniformly reaches the surface of cells.

In some other embodiments of the present invention, the V-shaped grooves have an opening width of 50 μm for the purpose of constructing a uniform reflective surface. The beneficial effect of the technical solution is: uniform tetrahedrons consistent with the prisms in size are constituted to ensure uniform reflection of light.

FIG. 8 shows an application of the photovoltaic reflective film. The photovoltaic reflective film is applied to a photovoltaic module 4 to improve the power of the photovoltaic module. The photovoltaic module 4 includes a plurality of cells 41 and welding strips 42 for connecting the cells, the photovoltaic reflective film is arranged on the upper surface of the welding strips 42, and/or arranged in gaps 45 between the cells 41. The photovoltaic reflective film is parallel to the gaps 45 in the length direction, and the photovoltaic reflective film is also parallel to the welding strips 42 in the length direction. The beneficial effect of the technical solution is: the photovoltaic reflective film is arranged at a spatial position where light is not utilized in the photovoltaic module, and the light is reflected to the surface of the cells and converted into electrical energy, so that the power generated by the photovoltaic module is improved.

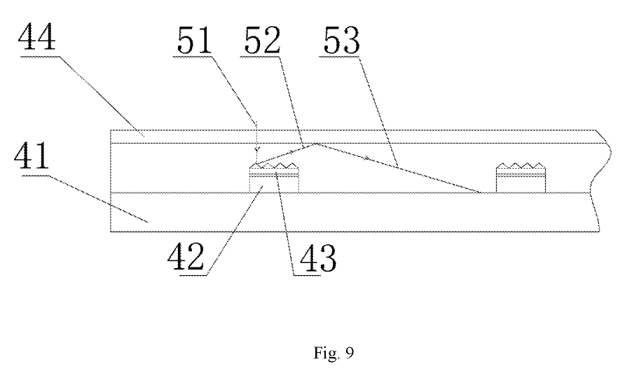

The following illustrates the principle of light reflection in the photovoltaic module according to the present invention with reference to FIG. 9. The photovoltaic reflective film 43 is attached to the surface of the welding strips 42. Incident light 51 (sunlight) is emitted to the reflective layer of the photovoltaic reflective film 43 through a glass sheet 44 and reflected to change the path to form reflected light 52, then the light is totally reflected by the surface of the glass sheet 44 to change the path to form total reflected light 53, the light finally reaches the cells 41, and the light energy is absorbed and converted into electric energy.

The foregoing embodiments are merely to illustrate the technical concept and characteristics of the present invention, and aim to allow those of ordinary skill in the art to understand the content of the present invention and implement the same, but the scope of the present invention is not limited thereto. All equivalent changes or modifications made according to the essence of the present invention should fall into the protection scope of the present invention.

1. A photovoltaic reflective film, comprising a substrate and a micro-structural reflective layer arranged on the upper surface of the substrate, wherein the micro-structural reflective layer comprises a micro-structural layer and a reflective layer coated on the surface of the micro-structural layer, wherein the micro-structural layer is composed of a plurality of polygonal pyramids, micro triangular prisms or micro-prisms.

2. The photovoltaic reflective film according to claim 1, further comprising a fixed adhesive layer or a back adhesive layer, wherein the fixed adhesive layer or the back adhesive layer is arranged on the lower surface of the substrate.

3. The photovoltaic reflective film according to claim 2, wherein the polygonal pyramids of the micro-structural layer are rectangular pyramids, and the bottom edges of the rectangular pyramids are arranged at an angle of 45° to the length direction of the substrate.

4. The photovoltaic reflective film according to claim 2, wherein the polygonal pyramids of the micro-structural layer are rectangular pyramids, the quadrangular pyramids have a multi-slope structure, and the angles of slopes of the ridges decrease successively from bottom to top.

5. The photovoltaic reflective film according to claim 2, wherein one side of the micro triangular prisms is arranged on the upper surface of the substrate, and the ridge direction of the micro triangular prisms is parallel to the length direction of the substrate.

6. The photovoltaic reflective film according to claim 5, wherein the top of the micro triangular prism is cut into a multi-pointed concave and convex structure.

7. The photovoltaic reflective film according to claim 1, wherein the ridge direction of the micro-prisms is arranged at an angle of 15°-65° to the length direction of the substrate.

8. The photovoltaic reflective film according to claim 7, wherein a plurality of W-shaped pointed structures are arranged on one side of the micro-prism.

9. The photovoltaic reflective film according to claim 8, wherein the micro-prism layer is provided with a plurality of V-shaped grooves, and the bottom edges of the V-shaped grooves are perpendicular to the bottom edges of the micro-prisms.

10. The photovoltaic reflective film according to claim 9, wherein the micro-prisms have a bottom width of 50 μm and an apex angle of 120°, and the V-shaped grooves have an opening width of 50 μm.

11. An application of the photovoltaic reflective film, wherein the photovoltaic reflective film claim 1 is applied to a photovoltaic module to improve the power of the photovoltaic module; the photovoltaic module comprises a plurality of cells and welding strips for connecting the cells; the photovoltaic reflective film is arranged on the upper surface of the welding strips or in the gaps between the cells; or the photovoltaic reflective film is simultaneously arranged on the upper surface of the welding strips and in gaps between the cells, and the length direction of the photovoltaic reflective film is parallel to the length direction of the welding strips or the length direction of the gaps.
